(19) United States
(12) Patent Application Publication
(10) Pub. No.: US 2007/0204972 A1
(43) Pub. Date: Sep. 6, 2007

(54) Method and apparatus for dissipating heat

(75) Inventors: Brian J. Edward, Jamesville, NY (US); Peter J. Ruzicka, Auburn, NY (US); Mark Sabatino, Jamesville, NY (US)

Correspondence Address: BURR & BROWN, PO BOX 7068, SYRACUSE, NY, 13261-7068, US

(73) Assignee: SENSIS CORPORATION, East Syracuse, NY (US)

(21) Appl. No.: 11/365,164

(22) Filed: Mar. 1, 2006

(51) Int. Cl. H05K 7/20

(52) U.S. Cl. 165/80.3; 361/704; 361/705; 165/185

(57) ABSTRACT

A heat dissipation device, comprises a base, a base element positioned within the base, and at least one heat exchange component mounted on the base. The at least one heat exchange component comprises at least one porous foam component (e.g., a metallized foam or a carbon foam), at least one fiber plate (e.g., comprising carbon fibers) and/or at least one corrugated metal element (e.g., comprising aluminum or copper). The device can further comprise at least one sliver (e.g., comprising diamond or carbon fiber). The device can further comprise at least one heat transfer piece (e.g., of diamond) positioned within the base. There is also provided a method of dissipating heat, comprising passing fluid, e.g., air, across at least one heat exchange component of such a device.

### FIELD OF THE INVENTION

The present invention relates to apparatus for dissipating heat. The present invention further relates to the thermal management of electronic components, and more particularly, limiting temperatures of components generating heat at very high density. The present invention further relates to methods of dissipating heat, e.g., from electronic components.

In preferred aspects, the present invention relates to apparatus for dissipating heat from electronic components, e.g., electronic components for a radar antenna.

### BACKGROUND OF THE INVENTION

Evolving electronic components are operating at higher speeds and higher power levels and are being packed more and more densely. As a consequence, these components are generating increasingly larger amounts of heat in smaller areas. To limit the temperatures of these components, and thereby realize peak performance plus reliable operation, this heat energy must be effectively removed.

The continued trend in digital electronic integrated circuits, such as computer processors, is to form more active devices (transistors) into smaller areas and to operate these devices at higher speeds. The by-product of this trend is the generation of very high heat densities. Removal of this heat has been identified as perhaps the biggest issue facing computer designers. Consequently, to support performance improvements, effective heat extraction techniques are essential. New transistor materials, such as silicon carbide, are being developed for both analog power and radio frequency (RF) devices. These materials enable generation, conversion, and management of much higher power levels than has been previously possible. Heat densities at the point of generation can be on the order of 7000 Watts per square millimeter peak, ten times the amount associated with current transistors. To fully realize the potential of these new material components, effective heat removal techniques are needed.

Opto-electronic components, such as laser diodes and photo-detectors, must be maintained within temperature bounds to operate properly. As their power levels increase, techniques for removal of their excess heat, so as to maintain preferred operational temperatures, are essential.

Next generation radar systems will be required to deliver high levels of performance and operational flexibility, feature exceptional reliability, and be amenable to growth in capability while being readily integrated into their host platforms. Active phased arrays afford significant radar performance capability while “tile” construct implementations yield minimum volume and weight systems, and effective air-cooling promotes reliable operation.

Phased arrays are configured from a plurality of individual radiating elements whose phase and amplitude states can be electronically controlled. The radiated energy from the collection of elements combines constructively (focused) so as to form a beam. The angular position of the beam is electronically redirected by controlling the elements' phases. The shape of the beam is altered by controlling both the elements' phases and amplitudes. Active phased array antennas include the initial low noise amplifier for receive and the final power amplifier for transmit with each individual radiator, in addition to the phase and amplitude control circuitry. These components are packaged into Transmit/Receive (T/R) modules and are distributed, with the radiating elements, over the array structure.

Tile array implementations package the phased array active circuits into low-profile modules which are disposed in a plane parallel to the radiating face of the array. This is in contrast to “brick” constructs which package the circuitry into higher profile modules which are disposed orthogonal to the face of the array. Tile construction yields relatively thin and hence low volume active phased arrays which are more readily adapted to the host platforms. The construction also results in minimizing weight, which is universally beneficial for all platforms.

### BRIEF SUMMARY OF THE INVENTION

The present invention provides thermally enhanced packages for high heat density electronic components which allow for extracting heat from extremely localized areas, effectively spreading this heat over a larger area, thereby decreasing its density, and efficiently transferring the heat to the equipment's cooling media. The package preferably incorporates a unique combination of high thermal conductivity and thermal-expansion matched materials. The high thermal conductivity of the materials (when provided) promotes heat conduction away from the components. The matched thermal expansion of the materials, to that of the components (when provided), minimizes the occurrences of the stresses in the components with temperature excursions.

In accordance with the present invention, there is provided a heat dissipation device comprising a base, a base element positioned within the base, and one or more heat exchange components extending from the base. The one or more heat exchange components comprise at least one member selected from among the group consisting of porous foams (described in more detail below), fiber plates (described in more detail below), corrugated metal elements (described in more detail below) and protrusions (described in more detail below).

The base element can, if desired, comprise one or more base element vias. The base element vias can, if desired, be filled with any suitable material. Preferably, if base element vias are present, they are filled with the same material that the base comprises.

As noted above, the one or more heat exchange components comprise at least one member selected from among the group consisting of porous foams, fiber plates, corrugated metal elements and protrusions.

Porous foam heat exchange components, if employed, can be of any desired shape and size. Porous foam heat exchange components, if included, can be attached to the base by any suitable method. Some or all of any porous foam heat exchange components can, if desired, comprise slivers made of any suitable material, e.g., diamond and/or carbon fiber.

Fiber plates, if employed, can comprise any desired kind of fiber or combinations of kinds of fibers. The fibers in such fiber plates can be oriented in any desired way, and preferably a substantial percentage of the fibers are arranged in a substantially similar orientation. Such orientation can be selected so as to route heat transfer in a desired direction. Such orientation can be any desired orientation, e.g., perpendicular to major surfaces of the fiber plate. Fiber plate heat exchange components, if employed, can be of any desired shape and size. Fiber plate heat exchange components, if included, can be attached to the base by any suitable method. Some or all of any fiber plate heat exchange components can, if desired, comprise slivers made of any suitable material, e.g., diamond and/or carbon fiber.

Corrugated metal elements, if employed, can comprise any desired metal or metals. Corrugated metal element heat exchange components, if employed, can be of any desired shape and size. One or more of the corrugations in any corrugated metal heat exchange components included in a heat dissipation device according to the present invention can be partially or completely filled with any desired material. Some or all of any corrugated metal heat exchange components can, if desired, comprise slivers made of any suitable material, e.g., diamond and/or carbon fiber. Corrugated metal heat exchange components, if included, can be attached to the base by any suitable method.

Protrusions, if included, can independently and individually comprise any desired material. Preferably, the protrusions comprise the same material that the base comprises. Each of the protrusions, if included, can independently and individually be of any desired shape. For example, representative suitable shapes for the protrusions include fins and pins. The devices according to the present invention can include protrusions of a variety of shapes, e.g., in representative examples, the protrusions in particular devices can consist of a plurality of fins, can consist of a plurality of pins, or can consist of a plurality of fins and a plurality of pins. Any protrusion can, if desired, comprise a protrusion element. Any of the protrusion elements can, if desired, have one or more protrusion element vias. For example, in a device which includes protrusions including one or more fins, a fin element can be positioned in each fin, and each fin element can have a plurality of fin element vias. Likewise, in a device which includes protrusions including one or more pins, a pin element can be positioned in each pin, and each pin element can have a plurality of pin element vias. Similarly, in a device which includes protrusions including one or more fins and one or more pins, a fin element can be positioned in each fin, each fin element can have a plurality of fin element vias, a pin element can be positioned in each pin, and each pin element can have a plurality of pin element vias.

Where the device comprises one or more protrusion elements which comprise one or more protrusion element vias, the protrusion element vias can be filled with any desired material. Preferably, the protrusion element vias are filled with the same material that the protrusions comprise.

Where the base element comprises one or more base element vias and the device comprises protrusions, one (or more) of the base element vias is preferably substantially aligned with one of the protrusions.

The device can, if desired, further comprise one or more heat transfer pieces (described in more detail below) positioned within the base.

Alternatively or additionally, the device can further comprise one or more high heat transfer slivers comprising, consisting essentially of and/or consisting of a material which provides high heat transfer properties, each of the one or more slivers each being positioned within one of the heat exchange components.

The present invention is further directed to methods of dissipating heat, comprising passing fluid (which can be gaseous or liquid, and which is preferably gaseous, a particularly preferred fluid being air) across one or more heat exchange components of devices according to the present invention as described above.

A thermally enhanced package design according to the present invention preferably employs all solid-type materials, i.e., no internal fluids. There is no fundamental factor which limits either the heat loads or temperature ranges at which it functions. Preferably, the package design is compact and self-contained. The package design lends itself to production of electronic assemblies by being producible, and consequently affordable, using developed manufacturing processes. By contrast, alternative approaches for thermally enhancing electronic packaging have typically limited heat load and temperature ranges, are typically bulky and complex, and/or difficult to fabricate, rendering them costly.

The thermally enhanced packages according to the present invention enable insertion of new electronic component technologies into commercial and military systems with application to computers, transportation, communications, sensors, opto-electronics, and industrial controls. With this component packaging, systems using air-based cooling can be extended to higher power levels, deferring the need to transition to liquid coolant. For the highest power systems, the thermally enhanced packaging may also be advantageously employed with a liquid coolant media.

The invention may be more fully understood with reference to the accompanying drawings and the following detailed description of the invention.

### BRIEF DESCRIPTION OF THE DRAWING FIGURES

FIG. 1 is a front view of a first embodiment of a heat dissipation device according to the present invention.

FIG. 2 is a cross-sectional view of the heat dissipation device shown in FIG. 1 taken along line 2-2 in FIG. 1.

FIG. 3 is a front view of the base element in the heat dissipation device depicted in FIG. 1.

FIG. 4 is a front view of a heat dissipation device according to a second embodiment of the present invention.

FIG. 5 is a cross-sectional view of the heat dissipation device shown in FIG. 4 taken along line 5-5 in FIG. 4.

FIG. 6 is a front view of the base element in the heat dissipation device shown in FIG. 4.

FIG. 7 is a side view a third embodiment of a heat dissipation device according to the present invention.

FIG. 8 is a front view of a fourth embodiment of a heat dissipation device according to the present invention.

FIG. 9 is a cross-sectional view of the heat dissipation device shown in FIG. 8 taken along line 9-9 in FIG. 8.

FIG. 10 is a front view of the base element in the heat dissipation device shown in FIG. 8.

FIG. 11 is a front view of a fifth embodiment of a heat dissipation device according to the present invention.

FIG. 12 is a cross-sectional view of the heat dissipation device shown in FIG. 11 taken along line 12-12 in FIG. 11.

FIG. 13 is an exploded schematic view of an embodiment of a thermally enhanced package for use in conjunction with air coolant media.

FIG. 14 is a front view of a heat dissipation device 10 according to an embodiment in accordance with the present invention.

FIG. 15 is a cross-sectional view taken along line 15-15 in FIG. 14.

FIG. 16 is a cross-sectional view taken along line 16-16 in FIG. 14.

FIG. 17 is a front view of the base element in the heat dissipation device shown in FIG. 14.

FIG. 18 is a cross-sectional view taken along line 18-18 in FIG. 17.

FIG. 19 is a cross-sectional view taken along line 19-19 in FIG. 14.

FIG. 20 is a front perspective view of another embodiment of a heat transfer element according to the present invention.

FIG. 21 is a rear perspective view of the embodiment of a heat transfer element depicted in FIG. 20.

FIG. 22 is a front view of a base element of another embodiment of a heat dissipation device according to the present invention.

### DETAILED DESCRIPTION OF THE INVENTION

As noted above, in accordance with the present invention, there is provided a heat dissipation device comprising a base, a base element positioned within the base, and one or more heat exchange components extending from the base.

The base can comprise any suitable material. Preferably, the base comprises a material which readily transfers heat. In one aspect, the base can comprise a metal matrix composite, i.e., a material made by infusing (e.g., by melting and injecting) a metal into a porous pre-form. For example, a representative example of a preferred base is a base which comprises AlSiC, preferably in the form of a metal matrix composite. In a preferred aspect of the present invention, the base consists of and/or consists essentially of AlSiC, preferably in the form of a metal matrix composite.

As noted above, the base element is positioned within the base.

The base element can be formed from any suitable material, preferably a material which has an extremely high heat transfer coefficient. An example of a particularly preferred material out of which the base element can be made is annealed pyrolytic graphite (APG).

The base and the base element can be configured in any suitable way. Preferably, the base has first and second sides which are substantially parallel with one another and the base element has first and second sides which are parallel with one another and which are also parallel with the first and second sides of the base.

Preferably, the rate of heat transfer within the base element is greater in a direction parallel to a major surface of the base element than it is in a direction which is perpendicular to that surface of the base element.

Preferably, the base element comprises a plurality of base element vias. Preferably, base element vias, if provided, extend through the base element, but alternatively, they may extend through only a portion of the thickness of the base element. Where the base element includes base element vias, the base element vias can optionally be partially or completely filled with any suitable material. Preferably, the base element vias, when present, are filled with the same material that the base comprises. Alternatively, the base element vias can be filled with any other suitable material, e.g., diamond slivers or carbon fiber slivers, or the base element vias can be partially filled with diamond slivers or carbon fiber slivers, with the remaining space being (1) unfilled, (2) filled with any desired material (e.g., the same material that the base comprises), or (3) partially filled with any desired material with the remainder being unfilled. Where the base element includes vias which are filled with the same material that the base comprises, heat transfer from the base element is enhanced. Where slivers are provided, such slivers can individually and independently be of any desired shape or shapes.

Where the base element comprises vias, the base element vias independently can extend in any desired direction or directions. Preferably, where the base element comprises base element vias, the base element vias each extend in a direction which is substantially perpendicular to a side (i.e., one of the major surfaces) of the base. Where the base element has base element vias and the device comprises protrusions, each of the base element vias is preferably substantially aligned with one of the protrusions.

The expression “aligned” as used herein, e.g., in the expression “each of the base element vias is substantially aligned with one of the protrusions” indicates that a plane substantially bisecting the protrusion (e.g., a fin) passes through the base element via from one side of the base element to the other side.

The expression “extends in a direction” when referring to a particular element, indicates that a line can be drawn in that direction which passes through that element.

The expression “fin” as used herein refers to a protrusion having two major dimensions and one minor dimension, preferably a structure which includes first and second substantially parallel sides.

As used herein, the term “substantially,” e.g., in the expressions “substantially aligned”, “substantially parallel”, “substantially bisecting”, and “substantially in a plane”, means at least about 90% correspondence (preferably 95% correspondence) with the feature recited, e.g., “substantially parallel” means that two planes diverge from each other at most by an angle of 10% of 90 degrees, i.e., 9 degrees (preferably 4.5 degrees); “substantially in a plane” means that a plane defined by any trio of points in the structure and a plane connecting any other trio of points in the structure define no angle greater than 10% of 90 degrees, i.e., 9 degrees (preferably 4.5 degrees).

The expression “substantially perpendicular”, as used herein, means that at least 90% (preferably 95%) of the points in the structure which is characterized as being substantially perpendicular to a reference plane are located on one of or between a pair of planes (1) which are perpendicular to the reference plane, (2) which are parallel to each other and (3) which are spaced from each other by a distance of not more than 10% (preferably 5%) of the largest dimension of the structure.

The expression “substantially linear”, as used herein, means that (1) a line connecting any pair of points which are both located in the portion of the plot which is substantially linear and which points are spaced by at least one fifth of the length of the portion of the plot, and (2) a line connecting any other pair of points in the portion of the plot which is substantially linear and which points are spaced by at least one fifth of the length of the portion of the plot, define an angle not greater than 9 degrees (preferably 4.5 degrees).

As noted above, the one or more heat exchange components can comprise at least one porous foam. Persons skilled in the art are familiar with a variety of porous foams suitable for heat transfer, and any such foams can be used according to the present invention. For example, suitable foams for use according to the present invention include metallized foams (e.g., aluminum or copper foam, or any other foam comprising metal having high thermal conductivity) or carbon foams.

Porous foam heat exchange components, if employed, can be of any desired shape and size. A representative example of a suitable shape for a porous foam heat exchange component is a right parallelepiped shape having first and second major surfaces which are substantially parallel to each other and to major surfaces of the base, and which has any suitable desired thickness.

Porous foam heat exchange components, if included, can be attached to the base by any suitable method, a variety of which are well-known to those of skill in the art, e.g., (1) by soldering, (2) by using an epoxy (preferably a thermally conductive epoxy, e.g., an epoxy loaded with silver particles), (3) by S-bonding, and/or (4) by welding, all of these types of attachment methods being well-known to those of skill in the art.

As indicated above, a heat dissipation device according to the present invention can comprise one or more porous foam heat exchange components. As discussed below, such a heat dissipation device can further comprise one or more fiber plates, one or more corrugated metal elements, and/or one or more protrusions.

Some or all of any porous foam heat exchange components or other heat exchange components can, if desired, comprise slivers made of any suitable material, e.g., diamond and/or carbon fiber.

As noted above, the one or more heat exchange components can comprise at least one fiber plate. Such fiber plates can comprise any desired kind of fiber or combinations of kinds of fibers. For example, suitable fiber plates for use according to the present invention include carbon fiber plates. The fibers in such fiber plates can be oriented in any desired way, and preferably a substantial percentage of the fibers, e.g., at least 25%, preferably at least 50% (e.g., at least 75%), are arranged in a substantially similar orientation. Such orientation can be selected so as to route heat transfer in a desired direction. Such orientation can be any desired orientation, e.g., perpendicular to major surfaces of the fiber plate.

Fiber plate heat exchange components, if employed, can be of any desired shape and size. A representative example of a suitable shape for a fiber plate heat exchange component is a right parallelepiped shape having first and second major surfaces which are substantially parallel to each other and to major surfaces of the base, and which has any suitable desired thickness.

Fiber plate heat exchange components, if included, can be attached to the base by any suitable method, a variety of which are well-known to those of skill in the art, e.g., (1) by soldering, (2) by using an epoxy (preferably a thermally conductive epoxy, e.g., an epoxy loaded with silver particles), (3) by S-bonding, and/or (4) by welding, all of these types of attachment methods being well-known to those of skill in the art.

As indicated above, a heat dissipation device according to the present invention can comprise one or more fiber plate heat exchange components (e.g., stacked in a laminate and/or positioned next to each other). As discussed below, such a heat dissipation device can further comprise one or more porous foam heat exchange components, one or more corrugated metal elements, and/or one or more protrusions.

Some or all of any fiber plate heat exchange components or other heat exchange components can, if desired, comprise slivers made of any suitable material, e.g., diamond and/or carbon fiber.

As noted above, the one or more heat exchange components can comprise at least one corrugated metal element. Such corrugated metal element can comprise any desired metal or metals, e.g., aluminum, copper, or any other metal with high heat transfer characteristics.

Corrugated metal element heat exchange components, if employed, can be of any desired shape and size. A representative example of a suitable shape for a corrugated metal element is a corrugated shape curved along lines which are substantially parallel to one another, such that the corrugated shape comprises a plurality of planar portions which are substantially parallel to one another and which are substantially perpendicular to major surfaces of the base.

One or more of the corrugations in any corrugated metal heat exchange components included in a heat dissipation device according to the present invention can be partially or completely filled with any desired material, preferably one or more material having high heat transfer properties, e.g., carbon or graphite. For example, all of the corrugations which are open toward a side opposite to the base can be unfilled, and all of the corrugations which are open toward the base can be filled with carbon or graphite.

Some or all of any corrugated metal heat exchange components or other heat exchange components can, if desired, comprise slivers made of any suitable material, e.g., diamond and/or carbon fiber.

Corrugated metal heat exchange components, if included, can be attached to the base by any suitable method, a variety of which are well-known to those of skill in the art, e.g., (1) by soldering, (2) by using an epoxy (preferably a thermally conductive epoxy, e.g., an epoxy loaded with silver particles), (3) by S-bonding, and/or (4) by welding, all of these types of attachment methods being well-known to those of skill in the art.

As indicated above, a heat dissipation device according to the present invention can comprise one or more corrugated metal heat exchange components. As discussed below, such a heat dissipation device can further comprise one or more porous foam heat exchange components, one or more fiber plates, and/or one or more protrusions.

As noted above, the one or more heat exchange components can comprise at least one protrusion. Such protrusions can be of any desired shape or shapes, and can be oriented in any desired orientation or orientations. Preferably, the protrusions, if included, are fins, pins, or a combination of fins and pins. If desired, protrusions can be shaped and arranged so as to assist in directing fluids relative to the heat dissipation device as desired.

The expression “pin” as used herein refers to a protrusion having one major dimension and two minor dimensions, the major dimension preferably extending substantially linearly.

Preferably, protrusions, if included, comprise a material which is the same as or similar to a material that the base comprises. In a preferred aspect, protrusions are made of the same material as the base.

Preferably, protrusions, if included, are integral with the base. Alternatively, protrusions, if included, can be attached to the base by any suitable method, a variety of which are well-known to those of skill in the art, e.g., (1) by soldering, (2) by using an epoxy (preferably a thermally conductive epoxy, e.g., an epoxy loaded with silver particles), (3) by S-bonding, and/or (4) by welding, all of these types of attachment methods being well-known to those of skill in the art.

Protrusions, if provided, can independently extend in any desired direction or directions from the base. Preferably, protrusions, if provided, each extend in a direction substantially perpendicular to a surface of the base. In a particularly preferred arrangement, the base has first and second sides, the protrusions comprise at least three fins, and each fin has first and second surfaces which are substantially perpendicular to the first side of the base.

Preferably, where protrusions are included, at least one protrusion element is positioned within each of at least one of the protrusions.

Protrusion elements, if included, independently and individually can be formed from any suitable material. Preferably, protrusion elements are formed from a material (or materials) which has an (or which have) extremely high heat transfer coefficient(s). An example of a particularly preferred material out of which the protrusion elements can be made is annealed pyrolytic graphite (APG). Other representative examples of materials out of which protrusion elements can be made include carbon fiber and graphite. Preferably, protrusion elements, if included, comprise a material which is the same as or similar to a material that the base element comprises. In a preferred aspect, the protrusion elements consist of the same material as the base element. Alternatively or additionally, some or all of any protrusions and/or the protrusion elements can comprise slivers made of any suitable material, e.g., diamond and/or carbon fiber. For example, protrusions can comprise cylindrical pins and can each include a cylindrical diamond sliver therewithin, or protrusions can comprise fins and can each include a plurality of generally cylindrical or square cross-sectional diamond slivers therewithin. Optionally, protrusion elements can extend into and through at least a portion of one or more base element vias.

Where the device includes protrusions in the shape of fins, the fins can include protrusion elements which comprise fin elements which preferably each have a plurality of fin element vias. Preferably, fin element vias, if provided, extend through the respective fin element, but alternatively, they may extend through only a portion of the thickness of the fin element.

Protrusions, if included, preferably comprise a material which is the same as or similar to a material that the base comprises, and in a preferred aspect, protrusions are made of the same material as the base. Where protrusions are provided and have protrusion element vias, the protrusion element vias are preferably at least partially filled with a material which comprises a material which is the same as or similar to the material that the base comprises, and are preferably filled with the same material out of which the base is made. Alternatively, protrusion element vias, if included, can be filled with any other suitable material, e.g., they can be at least partially filled with diamond slivers and/or carbon fibers. By providing a device in which protrusion element vias are filled with the same material out of which the protrusions are made, heat transfer from the protrusion elements is enhanced.

Where protrusions element vias are provided, the protrusion element vias can independently extend in any desired direction or directions. Where the device has fins and the fins have fin element vias, the fin element vias of each fin preferably extend in a direction substantially perpendicular to a surface of the fin in which the fin element vias are provided.

As noted above, the one or more heat exchange components can comprise combinations of more than one kind of components selected from among the group consisting of one or more porous foams, one or more fiber plates, one or more corrugated metal elements and one or more protrusions. The different kinds of heat exchange components, if employed, can be positioned beside one another, stacked on each other and/or embedded or otherwise incorporated within or enmeshed with one another.

For example, a porous foam heat exchange component can have notches in which fin-shaped heat exchange components are positioned. Alternatively, a porous foam can be formed around a plurality of previously-formed fin-shaped and/or pin-shaped heat exchange components (e.g., where the fin-shaped and/or pin-shaped heat exchange components comprise a material or materials which do not melt at the temperatures at which the porous foam is formed). Alternatively, approximately half of a surface of a base can be covered with one or more porous foam heat exchange components, approximately a quarter of the surface of the base can be covered with pin-shaped protrusion heat exchange components and approximately a quarter of the surface of the base can be covered with fin-shaped protrusion heat exchange components (in such a device, the respective heat exchange components can be oriented so as to guide cooling fluid in a desired pattern). Alternatively, approximately half of a surface of a base can be covered with one or more porous foam heat exchange components, and the other approximately half of the surface of the base can be covered with pin-shaped protrusion heat exchange components and fin-shaped protrusion heat exchange components interspersed among each other.

In summary, an endless variety of combinations of heat exchange components can be provided, and all such combinations are within the scope of the present invention.

Preferably, at least one electronic component (e.g., an integrated circuit component) is mounted on a side of the base which is opposite to the side on which the heat exchange component(s) are provided.

The expression “on”, e.g., as used in the preceding paragraph in the expression “mounted on”, or in the expression “stacked on”, means that the first structure which is “on” a second structure can be in contact with the second structure, or can be separated from the second structure by one or more intervening structures.

Preferably, the device further comprises one or more heat transfer pieces positioned within the base. A heat transfer piece, when provided, preferably has an extremely high heat transfer coefficient. Preferably, one or more heat transfer pieces are provided in a region of the base adjacent to a location or locations where high heat loads are expected, e.g., adjacent to a position on the base opposite to the protrusions on which an IC component which generates large amounts of heat is to be mounted.

Preferably, a heat transfer piece, when present, extends through the base element.

The heat transfer piece can, if desired, extend through almost the entire thickness of the base, in order to increase the heat conductivity through the thickness of the base. In many cases, it is desirable for the heat transfer piece to not extend to (or beyond) one or both of the surfaces of the base, e.g., when protrusions are to be attached to the base to facilitate attaching (for example, by soldering) such protrusions to the base.

A heat transfer piece or pieces, when provided, can be made of any suitable material, a particularly preferred example being diamond. Alternatively, the heat transfer piece or pieces can be formed of any other suitable material, e.g., an SiC plug with diamond deposited on its surface (e.g., by chemical vapor deposition). The one or more heat transfer pieces, when provided, can be of any desired size and/or shape.

The heat dissipation devices according to the present invention, and each component thereof, can be of any desired overall size and/or shape.

The present invention is further directed to methods of dissipating heat, comprising passing fluid (preferably gaseous, a particularly preferred fluid being air) across heat exchange component(s) of devices according to the present invention as discussed above. As mentioned above, however, the fluid can alternatively comprise liquid coolant.

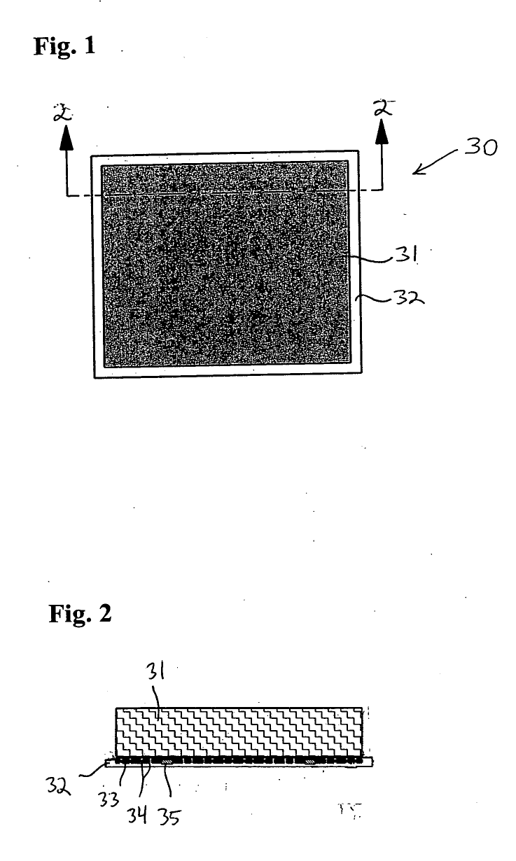

A first embodiment of a heat dissipation device according to the present invention is depicted in FIGS. 1-3.

FIG. 1 is a front view of the heat dissipation device 30 according to the first embodiment. The heat dissipation device 30 includes a porous foam heat exchange component 31 positioned on a base 32. The porous foam heat exchange component 31 is formed of carbon foam or metallized foam (e.g., carbon or aluminum).

FIG. 2 is a cross-sectional view of the heat dissipation device 12 shown in FIG. 1 taken along line 2-2 in FIG. 1. FIG. 2 shows the base 32 of the heat dissipation device 30, as well as a base element 33 positioned within the base 32. A plurality of base element vias 34 are formed in the base element 33. In addition, a plurality of heat transfer pieces 35 are positioned in the base element 33.

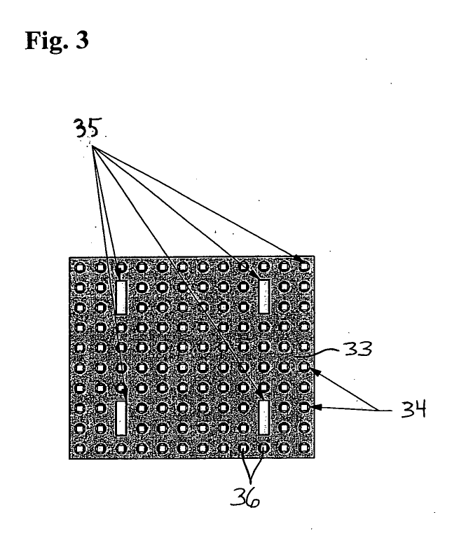

FIG. 3 is a front view of the base element 33 in the heat dissipation device 30. FIG. 3 shows the base element 33 and a plurality of base element vias 34 formed in the base element 33. FIG. 3 also shows four heat transfer pieces 35. Square cross-sectional slivers 36 are positioned in each of the cylindrical base element vias 34. The base 32 is formed of AlSiC, the base element 33 is formed of APG, the heat transfer pieces 35 are formed of CVD diamond, the slivers 36 are formed of CVD diamond and the portions of the base element vias which are not filled with slivers 36 are filled with AlSiC.

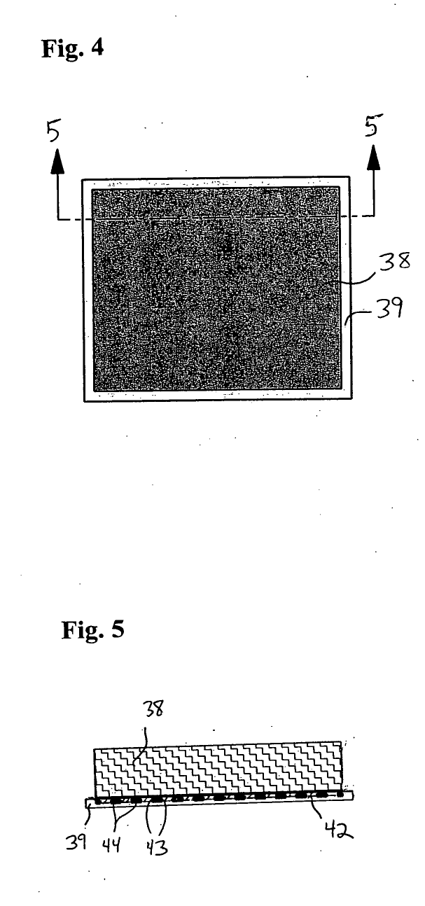

A second embodiment of a heat dissipation device according to the present invention is depicted in FIGS. 4-6.

FIG. 4 is a front view of the heat dissipation device 37 according to the second embodiment. The heat dissipation device 37 includes a porous foam heat exchange component 38 positioned on a base 39. The porous foam heat exchange component 38 is formed of carbon foam or metallized foam (e.g., carbon or aluminum).

FIG. 5 is a cross-sectional view of the heat dissipation device 37 shown in FIG. 4 taken along line 5-5 in FIG. 4. FIG. 5 shows the base 39 of the heat dissipation device 37, as well as a base element 42 positioned within the base 39. A plurality of base element vias 43 are formed in the base element 42, and cylindrical slivers 44 are positioned in each of the base element vias 43.

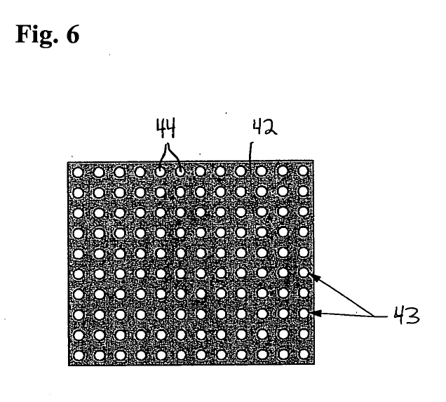

FIG. 6 is a front view of the base element 42 in the heat dissipation device 37. FIG. 6 shows the base element 42, the base element vias 43 and the cylindrical slivers 44. The base 39 is formed of AlSiC, the base element 42 is formed of APG, and the slivers 44 are formed of CVD diamond.

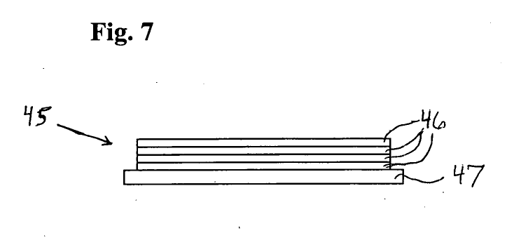

A third embodiment of a heat dissipation device according to the present invention is depicted in FIG. 7.

FIG. 7 is a side view of the heat dissipation device 45, which includes a plurality of fiber plate heat exchange components 46 stacked as a laminate and positioned on a base 47. The fiber plate heat exchange components 46 comprise carbon fiber plates.

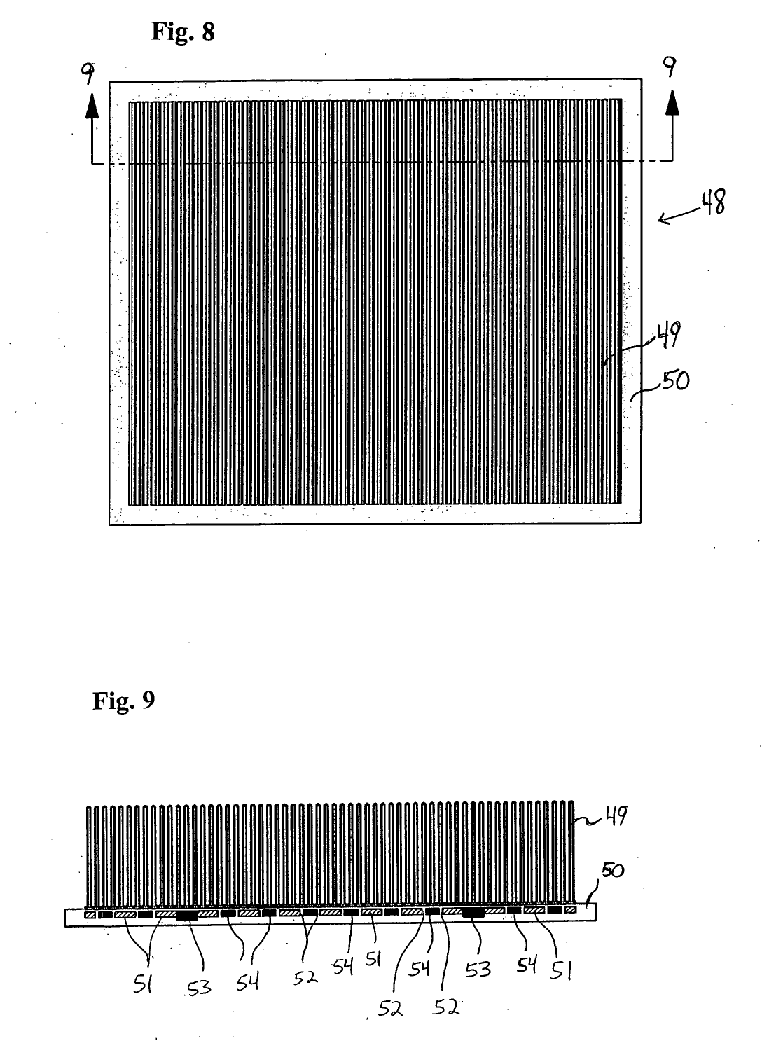

A fourth embodiment of a heat dissipation device according to the present invention is depicted in FIGS. 8-10.

FIG. 8 is a front view of the heat dissipation device 48 according to the fourth embodiment. The heat dissipation device 48 includes a corrugated metal element 49 positioned on a base 50.

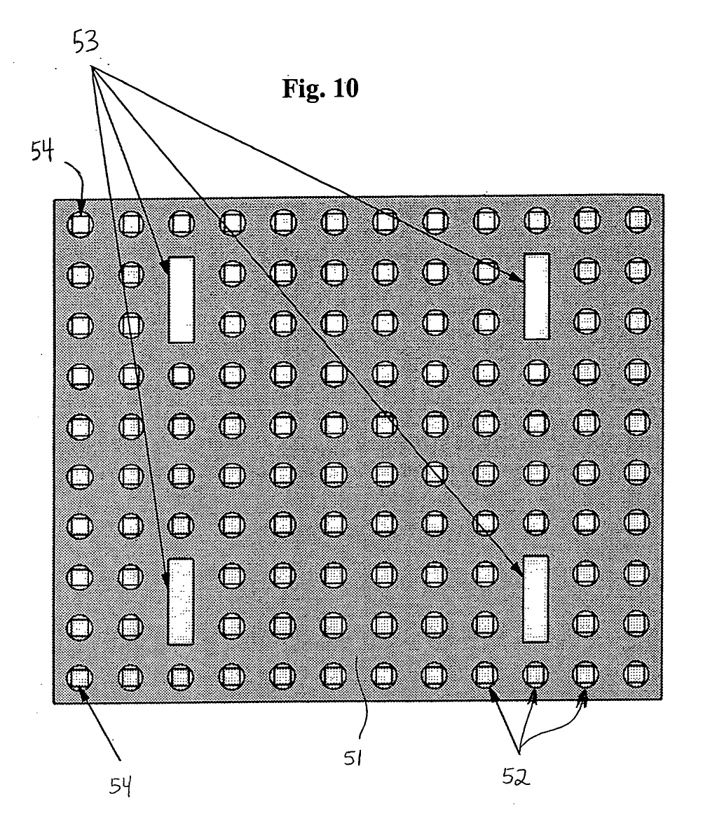

FIG. 9 is a cross-sectional view of the heat dissipation device 48 shown in FIG. 8 taken along line 9-9 in FIG. 8. FIG. 9 shows the base 50 of the heat dissipation device 48, as well as a base element 51 positioned within the base 50. A plurality of base element vias 52 are formed in the base element 51. In addition, a plurality of heat transfer pieces 53 are positioned in the base element 51. Slivers 54 are positioned in each of the base element vias 52.

FIG. 10 is a front view of the base element 51 in the heat dissipation device 48. FIG. 10 shows the base element vias 52, four heat transfer pieces 53, and the slivers 54. The base 50 is formed of AlSiC, the base element 51 is formed of APG, the heat transfer pieces 53 are formed of CVD diamond, the slivers 54 are formed of CVD diamond and the portions of the base element vias which are not filled with slivers 54 are filled with AlSiC.

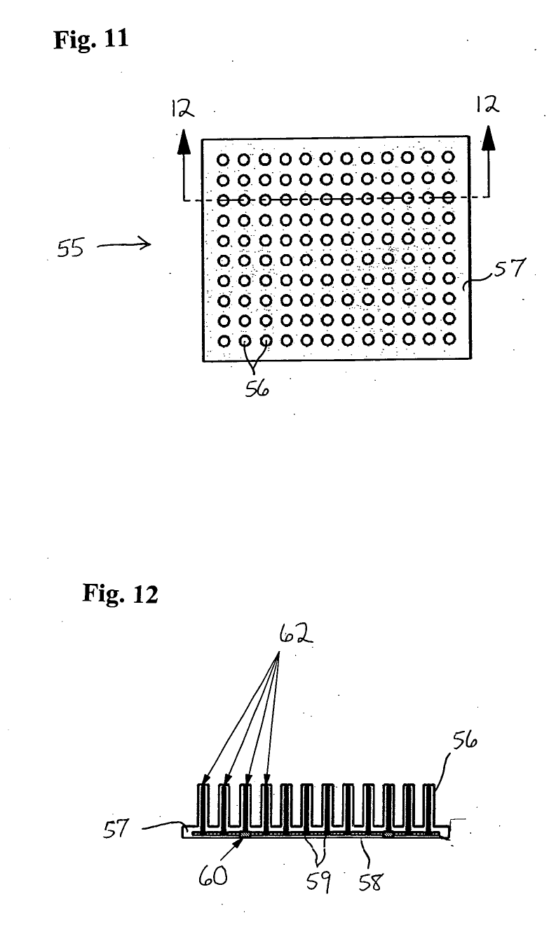

A fifth embodiment of a heat dissipation device according to the present invention is depicted in FIGS. 11-12.

FIG. 11 is a front view of the heat dissipation device 55 according to the fifth embodiment. The heat dissipation device 55 includes a plurality of pin-shaped protrusions 56 integral with and extending from a base 57.

FIG. 12 is a cross-sectional view of the heat dissipation device 55 shown in FIG. 11 taken along line 12-12 in FIG. 11. FIG. 12 shows the base 57 of the heat dissipation device 55, as well as a base element 58 positioned within the base 57. A plurality of base element vias 59 are formed in the base element 58. In addition, a plurality of heat transfer pieces 60 are positioned in the base element 58. A plurality of slivers 62 are also shown, each sliver 62 being positioned within one of the pin-shaped protrusions 56 and extending into one of the base element vias 59. The pin-shaped protrusions 56 and the base 57 are formed of AlSiC, the base element 58 is formed of APG, the heat transfer pieces 60 are formed of CVD diamond, and the slivers 62 are formed of CVD diamond (alternatively, the slivers 62 can comprise graphite, APG or carbon fibers).

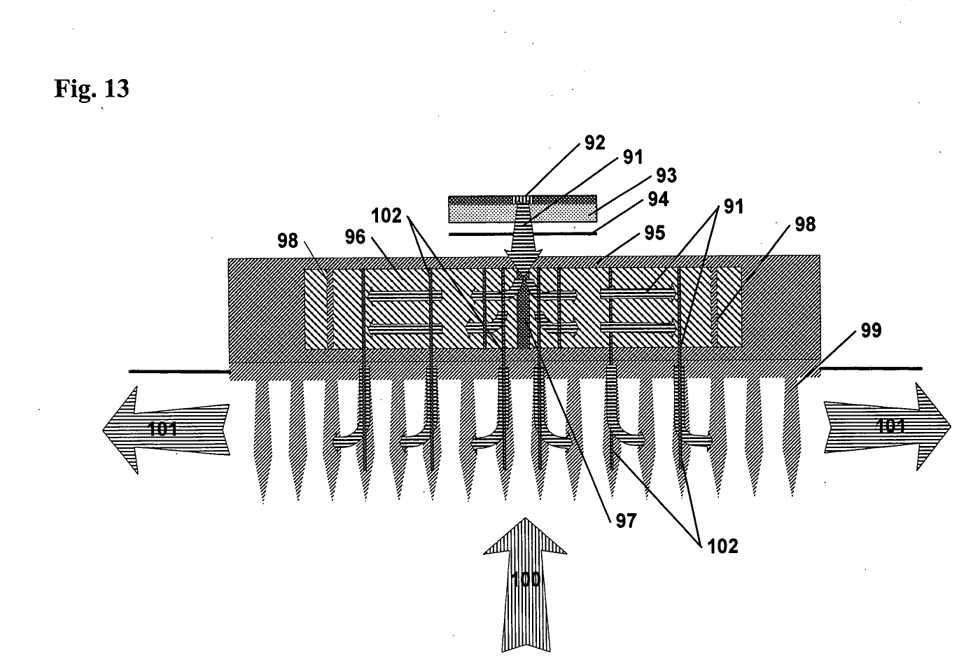

FIG. 13 depicts an embodiment of a thermally enhanced electronics package in accordance with the present invention in its application to components in their die or “chip” state, i.e., solid-state transistors or integrated circuits at their silicon, silicon carbide, gallium arsenide, etc. substrate material level. FIG. 13 shows a baseline package design. A single die is depicted, although the design is equally applicable for packaging multiple dies. Heat 91 generated at the transistor area 92 is conducted through the substrate material 93 to its bottom side.

Heat density is highest at the transistor area and can be, e.g., on the order of 7000 Watts peak, 1000 to 2000 Watts average per square millimeter for silicon carbide RF transmitter parts used in radar systems. Depending on the transistor type and its material composition, temperature at this heat origination area is to be limited to 125 to 175° C. for achieving high performance and reliable operation.

The substrate material thickness is typically minimized so as to limit the temperature gradient through it. For the above-referenced silicon carbide transmitter parts, the thickness may be on the order of 100 microns. Silicon carbide itself has a relatively high thermal conductivity of 160 W/mK. The die is attached to the thermally enhanced package by a metal solder 94 such as a gold-tin alloy. In many cases, solders are preferable to epoxy adhesives, as their thermal conductivity, approximately 55 W/mK, is typically on the order of 20 times higher than that of conductive epoxies. Alternatively, any other die attach methods can be employed, a variety of which are well-known to those skilled in the art.

The thermally enhanced package is comprised of aluminum silicon carbide (AlSiC) metal matrix composite 95 having an embedded heat spreader 96, 97. AlSiC features a high thermal conductivity of 200 W/mK; can be net-shape cast to accommodate die recesses and other package features, has a tailorable coefficient of thermal expansion (by composition of the AlSiC mix) to match that of the die, can capture electrical/RF feed-through features, and supports hermeticity. The embedded heat spreader is a combination of industrial diamond heat transfer pieces 97 placed through a sheet of annealed pyrolytic graphite (APG) material 96. APG features exceptional heat spreading properties having an in-plane (X-Y) thermal conductivity of 1350 to 1550 W/mK. The cross-plane (Z-axis) conductivity is comparatively rather low, only 10 to 20 W/mK. The diamond heat transfer pieces, however, have an extremely high isotropic conductivity of 1200 W/mK. Inserting the heat transfer pieces through the APG thereby provides a low impedance path for vertical conduction of heat 91 from under the die and into the high conductivity planes of the APG. The heat in the APG is now spread over a sufficient area to enable transfer into the electronic equipment's cooling media. The quantity of industrial diamond heat transfer pieces may be economized by featuring them most densely directly beneath the die and less so away from the die. Vertical conductivity through the APG may be additionally augmented by forming vias 98 through it and filling the vias 98 (partially or completely) with a material which has favorable heat conduction properties, preferably the same material that the base comprises (e.g., AlSiC). These vias are formed integral to the metal matrix package. The embodiment depicted in FIG. 13 further includes diamond slivers 102 which extend into the protrusions 99.

FIG. 13 illustrates the thermally enhanced packing adapted for air cooling. Heat exchanging protrusions 99 are formed on the base of the AlSiC package. Making the protrusions integral to the package is preferable to attaching them as a separate part as the thermal impedance of such an interface is avoided. The inlet coolant air 100 may flow in the plane of the heat exchanger or impinge normal to the heat exchanger as depicted in FIG. 13. Normal impingement is preferred as it promotes more effective heat transfer from the protrusions to the air. The coolant air, now containing the heat which originated at the die, is exhausted to the package sides 101.

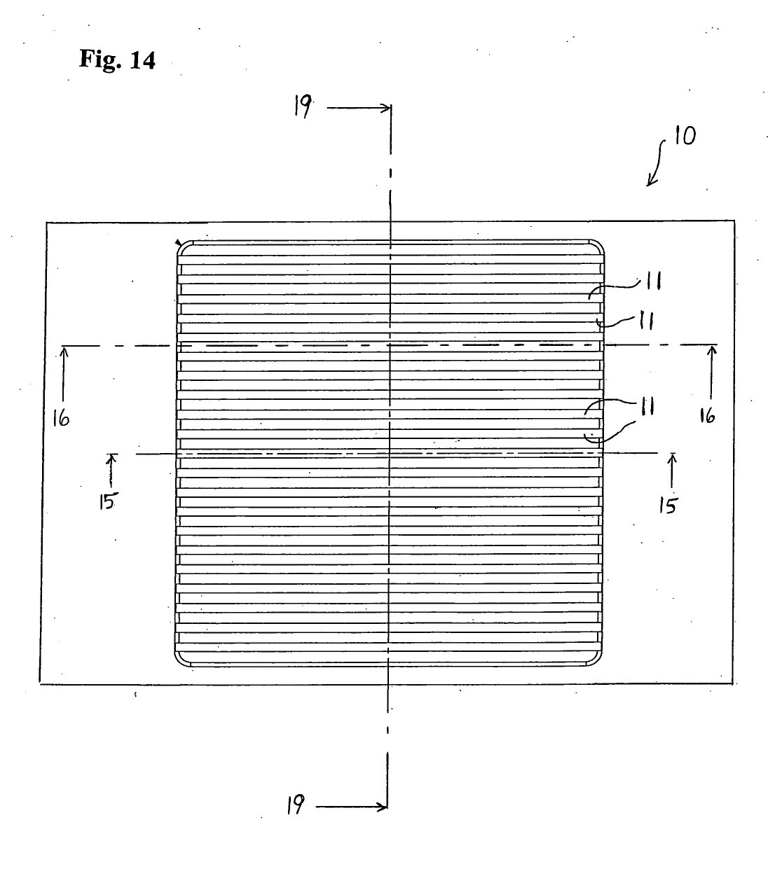

Another embodiment of a heat dissipation device according to the present invention is depicted in FIGS. 14-19.

FIG. 14 is a front view of the heat dissipation device 10 according to the embodiment depicted in FIGS. 14-19. The heat dissipation device 10 includes a plurality of protrusions 11 (in this case, the protrusions 11 are fins).

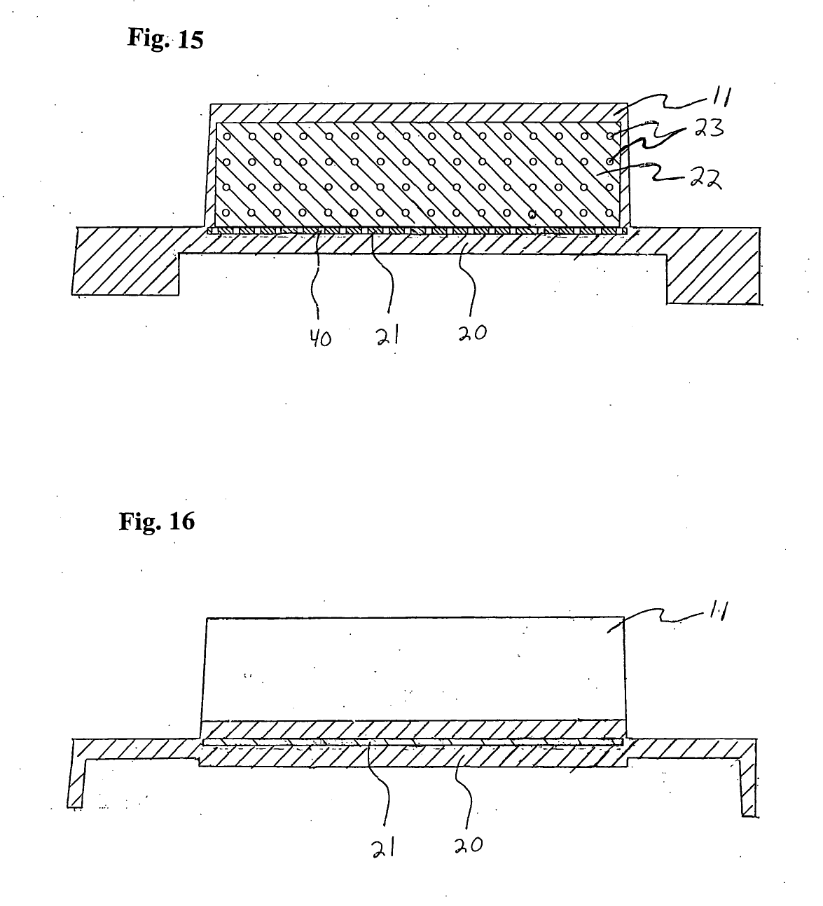

FIG. 15 is a cross-sectional view of the heat dissipation device 10 shown in FIG. 14 taken along line 15-15 in FIG. 14. FIG. 15 shows the base 20 of the heat dissipation device 10, as well as a protrusion element 22 (in this case, a fin element) positioned within one of the fins 11. The protrusion element 22 includes a plurality of protrusion element vias 23. FIG. 15 also depicts a base element 21 positioned within the base 20.

FIG. 16 is a cross-sectional view of the heat dissipation device 10 taken along line 16-16 in FIG. 14, through a plane in which no protrusion 11 is present. Accordingly, from the view shown in FIG. 16, only the base 20 and the base element 21 are seen in cross-section.

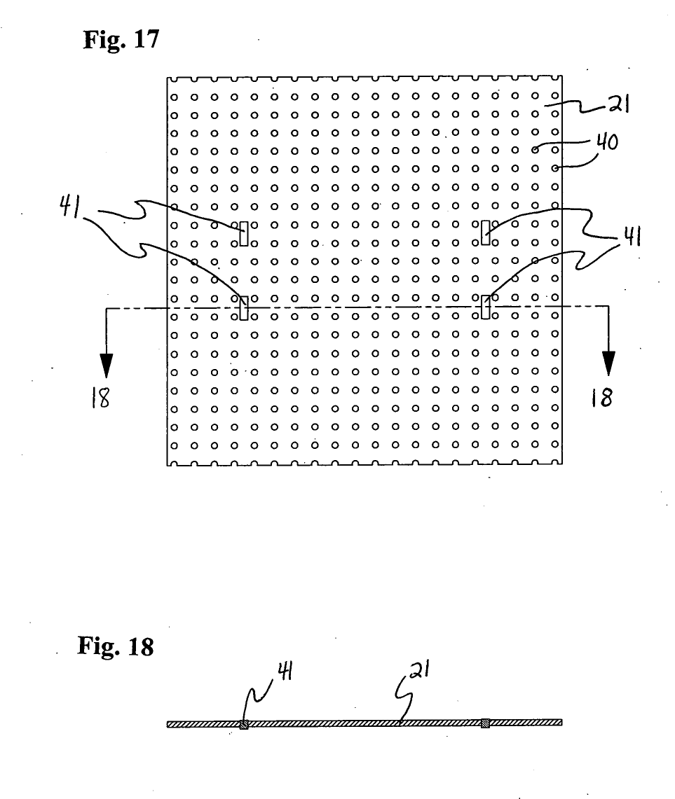

FIG. 17 is a front view of the base element 21 in the heat dissipation device 10. FIG. 17 shows the base element 21 and a plurality of base element vias 40 formed in the base element 21. FIG. 17 also shows four heat transfer pieces 41. FIG. 18 is a cross-sectional view taken along the line 18-18 in FIG. 17. FIG. 18 shows that the heat transfer pieces 41 extend through the base element 21.

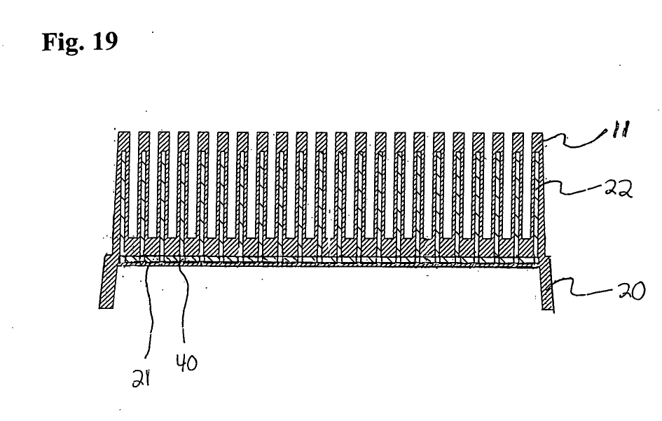

FIG. 19 is a cross-sectional view of the heat dissipation device 10 taken along line 19-19 in FIG. 14. From FIG. 19, it can be seen that the protrusion elements 22 are aligned with base element vias 40 in the base element 21.

In the embodiment shown in FIGS. 14-19, the base 20 and the fins 11 are integral and are formed of AlSiC, while the protrusion elements 22 and the base element 21 are formed of APG. The protrusion element vias 23 and the base element vias 40 are filled with AlSiC. The heat transfer pieces 41 are formed of diamond.

IC components are mounted on the base 20 on the rear side thereof, i.e., on the side opposite the front side as shown in FIG. 14. The IC components can be mounted in any desired orientation. Preferably, the regions of greatest heat intensity are located opposite the heat transfer pieces 41 relative to the base 20. The rear side of the base 20 can be configured in any desired orientation in order to accommodate the IC components which are mounted thereon, e.g., the rear side of the base 20 can be in the form of a “quad pack”, such “quad packs” being well-known in the art.

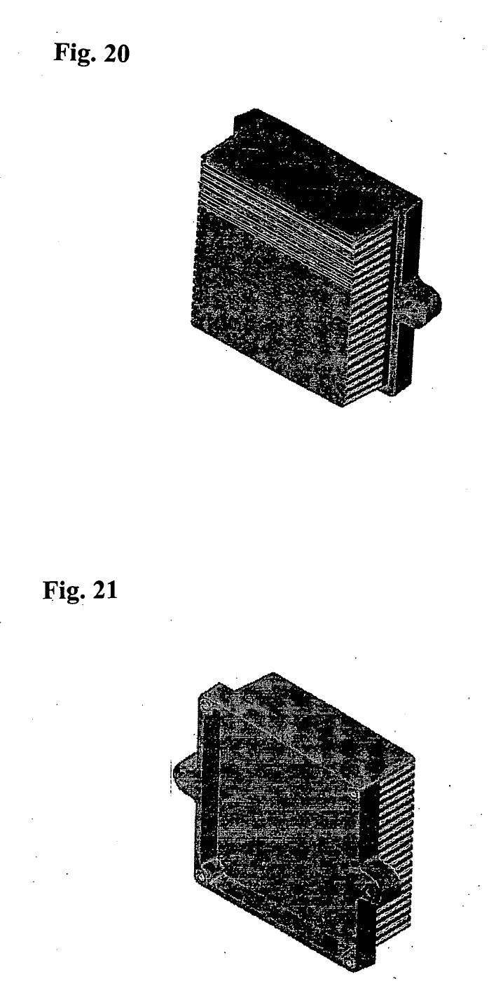

FIG. 20 is a front perspective view of another embodiment of a heat transfer element according to the present invention.

FIG. 21 is a rear perspective view of the embodiment of a heat transfer element depicted in FIG. 20.

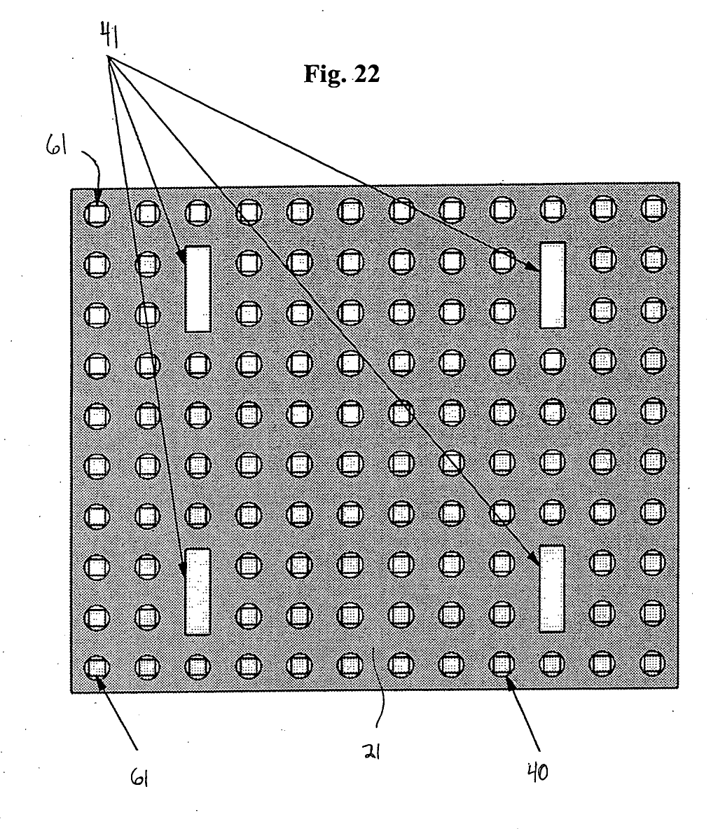

FIG. 22 depicts a front view of a base element of another embodiment of a heat dissipation device according to the present invention. The embodiment depicted in FIG. 22 is similar to the embodiment depicted in FIGS. 14-19, except that in the embodiment depicted in FIG. 22, additional diamond slivers 61 (i.e., in addition to the diamond heat transfer pieces 41) are positioned in the base element vias 40. In this embodiment, the diamond slivers 61 extend into the fins (alternatively, the diamond slivers 61 could not extend into the fins). Also, as can be seen in FIG. 22, the diamond slivers 61 have square cross-sections, and they do not completely fill the base element vias 40 (alternatively, the diamond slivers 61 can be of any other shape, e.g., they can be cylindrical, and they can optionally completely fill one or more of the base element vias 40, and/or in cases where the diamond slivers 61 do not completely fill the base element vias 40, rather than the remaining spaces being empty, such remaining spaces can be partially or completely filled with any suitable material or materials).

Any two or more structural parts of the devices described herein can be integrated. Any structural part of the devices described herein can be provided in two or more parts which are held together, if necessary. Similarly, any two or more functions can be conducted simultaneously, and/or any function can be conducted in a series of steps.

1. A heat dissipation device, comprising:
a base, said base comprising a first material;
a base element positioned within said base, said base element comprising a second material; and
at least one heat exchange component mounted on said base, said heat exchange component comprising porous foam.

2. A heat dissipation device as recited in claim 1, wherein said base element comprises a plurality of base element vias, at least a portion of at least one of said base element vias being filled with base element via filler material, said base element via filler material comprising said first material.

3. A heat dissipation device as recited in claim 1, wherein said porous foam comprises a metallized foam.

4. A heat dissipation device as recited in claim 3, wherein said metallized foam comprises at least one metal selected from the group consisting of aluminum and copper.

5. A heat dissipation device as recited in claim 1, wherein said porous foam comprises carbon foam.

6. A heat dissipation device as recited in claim 1, further comprising at least one element selected from the group consisting of at least one fiber plate mounted on said base, at least one corrugated metal element mounted on said base, and at least one protrusion mounted on said base.

7. A heat dissipation device as recited in claim 6, wherein said at least one protrusion is in contact with said base.

8. A heat dissipation device as recited in claim 6, further comprising at least one sliver positioned within at least one element selected from among said porous foam, said at least one fiber plate, said at least one corrugated metal element and said at least one protrusion.

9. A heat dissipation device as recited in claim 8, wherein said sliver comprises at least one material selected from the group consisting of diamond and carbon fiber.

10. A heat dissipation device as recited in claim 6, wherein said at least one protrusion comprises a material which is the same as a material that said base comprises.

11. A heat dissipation device as recited in claim 6, wherein at least one of said protrusions has at least one protrusion element positioned therein.

12. A heat dissipation device as recited in claim 1, further comprising at least one heat transfer piece positioned within said base.

13. A heat dissipation device as recited in claim 12, wherein said heat transfer piece comprises diamond.

14. A heat dissipation device as recited in claim 1, further comprising at least one sliver positioned within said porous foam.

15. A heat dissipation device as recited in claim 14, wherein said sliver comprises at least one material selected from the group consisting of diamond and carbon fiber.

16. (canceled)

17. A heat dissipation device, comprising:
a base, said base comprising a first material;
a base element positioned within said base, said base element comprising a second material; and
at least one heat exchange component mounted on said base, said heat exchange component comprising at least one fiber plate.

18. A heat dissipation device as recited in claim 17, wherein said base element comprises a plurality of base element vias, at least a portion of at least one of said base element vias being filled with base element via filler material, said base element via filler material comprising said first material.

19. A heat dissipation device as recited in claim 17, wherein said fiber plate comprises carbon fibers.

20. A heat dissipation device as recited in claim 17, wherein at least 25% of fibers contained in said fiber plate are arranged in a substantially similar orientation.

21. (canceled)

22. A heat dissipation device as recited in claim 17, further comprising at least one element selected from the group consisting of at least one corrugated metal element mounted on said base, and at least one protrusion mounted on said base.

23. A heat dissipation device as recited in claim 22, further comprising at least one sliver positioned within at least one element selected from among said fiber plate, said at least one corrugated metal element and said at least one protrusion.

24. A heat dissipation device as recited in claim 23, wherein said sliver comprises at least one material selected from the group consisting of diamond and carbon fiber.

25. A heat dissipation device as recited in claim 22, wherein said at least one protrusion comprises a material which is the same as a material that said base comprises.

26. A heat dissipation device as recited in claim 17, further comprising at least one heat transfer piece positioned within said base.

27. A heat dissipation device as recited in claim 26, wherein said heat transfer piece comprises diamond.

28. A heat dissipation device as recited in claim 17, further comprising at least one sliver positioned within said fiber plate.

29. A heat dissipation device as recited in claim 28, wherein said sliver comprises at least one material selected from the group consisting of diamond and carbon fiber.

30. (canceled)

31. A heat dissipation device, comprising:
a base, said base comprising a first material;
a base element positioned within said base, said base element comprising a second material; and
at least one heat exchange component mounted on said base, said heat exchange component comprising a corrugated metal element.

32. A heat dissipation device as recited in claim 31, wherein said base element comprises a plurality of base element vias, at least a portion of at least one of said base element vias being filled with base element via filler material, said base element via filler material comprising said first material.

33. A heat dissipation device as recited in claim 31, wherein said corrugated metal element comprises at least one metal selected from the group consisting of aluminum and copper.

34. A heat dissipation device as recited in claim 31, wherein at least one of the corrugations in said corrugated metal element is at least partially filled with at least one heat transfer material.

35. A heat dissipation device as recited in claim 34, wherein said heat transfer material comprises at least one material selected from the group consisting of carbon and graphite

36. A heat dissipation device as recited in claim 31, further comprising at least one protrusion mounted on said base.

37. A heat dissipation device as recited in claim 36, further comprising at least one sliver positioned within at least one element selected from among said corrugated metal element and said at least one protrusion.

38. A heat dissipation device as recited in claim 37, wherein said sliver comprises at least one material selected from the group consisting of diamond and carbon fiber.

39. A heat dissipation device as recited in claim 36, wherein said at least one protrusion comprises a material which is the same as a material that said base comprises.

40. A heat dissipation device as recited in claim 36, wherein at least one of said protrusions has at least one protrusion element positioned therein.

41. A heat dissipation device as recited in claim 31, further comprising at least one heat transfer piece positioned within said base.

42. A heat dissipation device as recited in claim 41, wherein said heat transfer piece comprises diamond.

43. A heat dissipation device as recited in claim 31, further comprising at least one sliver positioned within said corrugated metal.

44. A heat dissipation device as recited in claim 43, wherein said sliver comprises at least one material selected from the group consisting of diamond and carbon fiber.

45. (canceled)

46. A method of dissipating heat, comprising passing fluid across at least one heat exchange component of a device as recited in claim 1.

47. (canceled)

48. (canceled)

49. A method of dissipating heat, comprising passing fluid across at least one heat exchange component of a device as recited in claim 17.

50. A method of dissipating heat, comprising passing fluid across at least one heat exchange component of a device as recited in claim 31.
